(19) United States
(12) Patent Application Publication
(10) Pub. No.: US 2023/0278713 A1
(43) Pub. Date: Sep. 7, 2023

(54) POWER UNIT CONTROL SYSTEM, POWER UNIT CONTROL METHOD, AND POWER UNIT CONTROL PROGRAM

(71) Applicant: HONDA MOTOR CO., LTD., Tokyo (JP)

(72) Inventors: Daiko Tsutsumi, Wako-shi (JP); Masashi Eto, Wako-shi (JP); Hiroshi Sawamura, Wako-shi (JP)

(21) Appl. No.: 18/114,297

(22) Filed: Feb. 27, 2023

(30) Foreign Application Priority Data
Mar. 7, 2022 (JP) 2022-034307

(51) Int. Cl. B64D 27/02; F02C 9/44

(52) U.S. Cl. CPC B64D 27/02; F02C 9/44; H03M 1/12

(57) ABSTRACT

A power unit control system includes: a gas turbine including a turbine rotor; an energy converter being able to operate as a power generator that generates electric power with rotation of the gas turbine; a battery that stores electric power generated by the energy converter; a reception portion that receives a signal which is transmitted from a device controller that controls a device operating using the electric power stored in the battery or electric power generated by the energy converter; and a control portion that performs rotation speed increase control which increases the rotation speed of the gas turbine to a predetermined rotation speed when a predetermined first signal is received by the reception portion.

### CROSS-REFERENCE TO RELATED APPLICATION

Priority is claimed on Japanese Patent Application No. 2022-034307, filed on Mar. 7, 2022, the contents of which are incorporated herein by reference.

### BACKGROUND

### Field of the Invention

The present invention relates to a power unit control system, a power unit control method, and a power unit control program.

### Background

The temperature of an outer edge part of a turbine rotor increases rapidly when a gas-turbine engine starts.

Accordingly, a difference in temperature occurs between the outer edge part and a central part of the turbine rotor. Thereafter, the temperature of the central part of the turbine rotor increases slowly due to thermal conduction from the outer edge part. During this, in the metallic inside of the turbine rotor, thermal stress is generated due to a temperature gradient. This thermal stress causes metal fatigue in the turbine rotor and causes reduction of a lifespan of a gas turbine. Regarding this problem, a technique of heating the turbine rotor from the central part thereof by a magnetic field generating mechanism being attached to a rotation shaft of the gas turbine and reducing a difference in temperature between the outer edge part and the central part of the turbine rotor, whereby occurrence of thermal stress is prevented, is known in the related art (see Published Japanese Translation No. 2008-533366 of the PCT International Publication).

### SUMMARY

However, in the technique described in Published Japanese Translation No. 2008-533366 of the PCT International Publication, since the magnetic field generating mechanism needs to be installed in the gas-turbine engine, there is a problem with an increase in size, weight, and cost of a device.

An objective of an aspect of the present invention is to provide a power unit control system, a power unit control method, and a power unit control program that can prevent an increase in size, weight, and cost of a device and extend a lifetime of a gas turbine. Specifically, an objective of an aspect of the present invention is to provide a power unit control system, a power unit control method, and a power unit control program that can extend a lifetime of a gas turbine by preventing occurrences of metal fatigue of a turbine rotor of the gas turbine.

A power unit control system according to a first aspect of the present invention includes: a gas turbine including a turbine rotor; an energy converter being able to operate as a power generator that generates electric power with rotation of the gas turbine; a battery that stores electric power generated by the energy converter; a reception portion that receives a signal which is transmitted from a device controller that controls a device operating using the electric power stored in the battery or electric power generated by the energy converter; and a control portion that performs rotation speed increase control which increases the rotation speed of the gas turbine to a predetermined rotation speed when a predetermined first signal is received by the reception portion.

A second aspect is the power unit control system according to the first aspect, wherein the energy converter may operate as an electric motor that accelerates rotation of the gas turbine using electric power stored in the battery when the control portion performs the rotation speed increase control.

A third aspect is the power unit control system according to the second aspect, wherein the control portion may reduce the amount of fuel which is supplied to the gas turbine when the control portion performs the rotation speed increase control.

A fourth aspect is the power unit control system according to any one of the first to third aspects, wherein the control portion may perform rotation speed decrease control that decreases the rotation speed of the gas turbine to a predetermined rotation speed when a predetermined second signal is received by the reception portion, and the control portion may increase a load of the power generator such that the rotation speed decreases in the rotation speed decrease control.

A fifth aspect is the power unit control system according to any one of the first to fourth aspects, wherein the device may be a flying object, and the predetermined first signal may be a check completion signal indicating that the flying object is prepared for start of flight before the flying object flies by autonomous driving or a pilot's steering of the flying object.

A power unit control method according to a sixth aspect of the present invention includes: a reception step of receiving a signal which is transmitted from a device controller that controls a device including a gas turbine including a turbine rotor, an energy converter being able to operate as a power generator that generates electric power with rotation of the gas turbine, and a battery that stores electric power generated by the energy converter, the device operating using the electric power stored in the battery or electric power generated by the energy converter; and a control step of performing rotation speed increase control that increases the rotation speed of the gas turbine to a predetermined rotation speed when a predetermined signal is received in the reception step.

A seventh aspect of the present invention is a non-transitory computer-readable recording medium that includes a power unit control program, the power unit control program causing a computer to perform: a reception step of receiving a signal which is transmitted from a device controller that controls a device including a gas turbine including a turbine rotor, an energy converter being able to operate as a power generator that generates electric power with rotation of the gas turbine, and a battery that stores electric power generated by the energy converter, the device operating using the electric power stored in the battery or electric power generated by the energy converter; and a control step of performing rotation speed increase control that increases the rotation speed of the gas turbine to a predetermined rotation speed when a predetermined signal is received in the reception step.

According to the first to fifth aspects described above, the power unit control system can more rapidly change a centrifugal force acting on the turbine rotor of the gas turbine by changing the rotation speed of the gas turbine for a shorter time, reduce thermal stress generated inside the metal of the turbine rotor, and thereby prevent occurrences of metal fatigue. Further, according to the first to fifth aspects, for example, since a new device such as a magnetic field generating mechanism does not need to be installed in the power unit control system, it is possible to prevent an increase in size, weight, and cost of the device.

According to the second aspect, the power unit control system causes the energy converter to operate as an electric motor that accelerates rotation of the gas turbine when the rotation speed of the gas turbine is increased for a shorter time, and thereby, it is possible to more rapidly increase the rotation speed and to compensate for a responsiveness delay of the gas turbine.

According to the third aspect, since the power unit control system can prevent an input of heat to the turbine rotor by increasing the rotation speed of the gas turbine without increasing the amount of fuel supplied to the gas turbine, it is possible to reduce thermal stress generated inside the metal of the turbine rotor and to prevent occurrences of metal fatigue.

According to the fourth aspect, the power unit control system more rapidly decreases the centrifugal force that acts on the turbine rotor of the gas turbine by decreasing the rotation speed of the gas turbine for a shorter time and reduces tensile stress generated inside the metal of the turbine rotor, and thereby, it is possible to prevent occurrences of metal fatigue.

According to the fifth aspect, since the power unit control system can reliably operate the power unit after the flying object has been prepared for start of flight before the flying object flies, it is possible to more safely control the power unit. Further, since the power unit control system can operate the power unit at a timing at which the flying object has been prepared for start of flight before the flying object flies, it is possible to more efficiently supply power to the flying object.

### BRIEF DESCRIPTION OF THE DRAWINGS

FIG. 1 is a diagram schematically illustrating a flying object in which a power unit control system is mounted.

FIG. 2 is a diagram illustrating an example of a functional configuration of a flying object.

FIG. 3 is a diagram illustrating a flight state of the flying object.

FIG. 4 is a flowchart illustrating operations of the power unit control system.

FIG. 5 is a diagram illustrating rotation control of a gas-turbine engine (GT) of the power unit control system at the time of taking off through comparison with a comparative example.

FIG. 6 is a diagram illustrating rotation control of the gas-turbine engine (GT) of the power unit control system through comparison with a comparative example.

FIG. 7 is a diagram illustrating an example of a simulation result for reducing thermal stress in the power unit control system.

FIG. 8 is a diagram illustrating an example of a simulation result for reducing thermal stress in the power unit control system.

FIG. 9 is a diagram illustrating an example of a stress distribution of a turbine rotor according to a comparative example.

FIG. 10 is a view that focuses on part of the turbine rotor illustrated in FIG. 9.

FIG. 11 is a diagram illustrating torque control which is performed by the power unit control system when the rotation speed of the gas-turbine engine (GT) increases.

FIG. 12 is a diagram illustrating an example of a required output corresponding to FIG. 11.

### DESCRIPTION OF EMBODIMENTS

Hereinafter, a power unit control system, a power unit control method, and a power unit control program according to an embodiment of the present invention will be described with reference to the accompanying drawings.

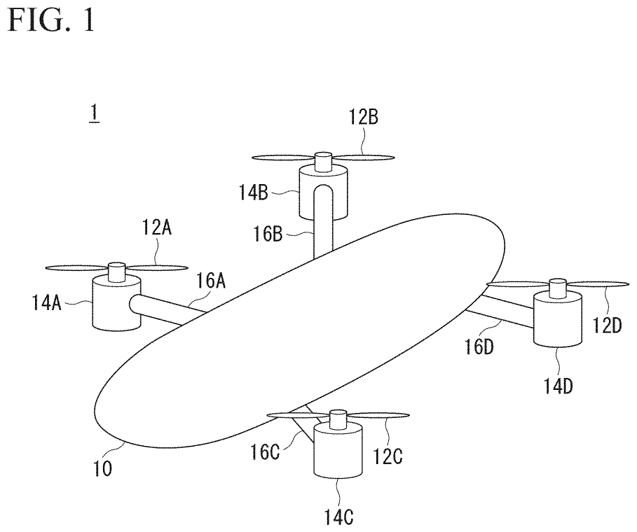

FIG. 1 is a diagram schematically illustrating a flying object 1 in which a power unit control system is mounted.

The flying object 1 includes, for example, an airframe 10, a plurality of rotors 12A to 12D, a plurality of electric motors 14A to 14D, and a plurality of arms 16A to 16D. In the following description, the plurality of rotors 12A to 12D are referred to as a “rotor 12” when they are not distinguished from each other, and the plurality of electric motors 14A to 14D are referred to as an electric motor 14 when they are not distinguished from each other. The flying object 1 may be a manned flying object or may be an unmanned flying object. The flying object 1 is not limited to a multicopter illustrated in the drawing, and may be a helicopter or a compound flying object including both a rotary wing and a fixed wing.

The rotor 12A is attached to the airframe 10 via the arm 16A. The electric motor 14A is attached to a base (a rotation shaft) of the rotor 12A. The electric motor 14A drives the rotor 12A. The electric motor 14A is, for example, a brushless DC motor. The rotor 12A is a fixed wing with blades rotating around an axis parallel to the gravitational direction when the flying object 1 takes a horizontal posture. The rotors 12B to 12D, the arms 16B to 16D, and the electric motors 14B to 14D have the same functional configuration as described above and thus a description thereof will be omitted.

When the rotors 12 rotate in accordance with a control signal, the flying object 1 flies in a desired flight state. The control signal is a signal for controlling the flying object 1 based on an operator's operation or an instruction in autonomous steering. For example, when the rotor 12A and the rotor 12D rotate in a first direction (for example, clockwise) and the rotor 12B and the rotor 12C rotate in a second direction (for example, counterclockwise), the flying object 1 flies. An auxiliary rotor for posture stability or horizontal propulsion or the like which is not illustrated may be provided in addition to the rotors 12.

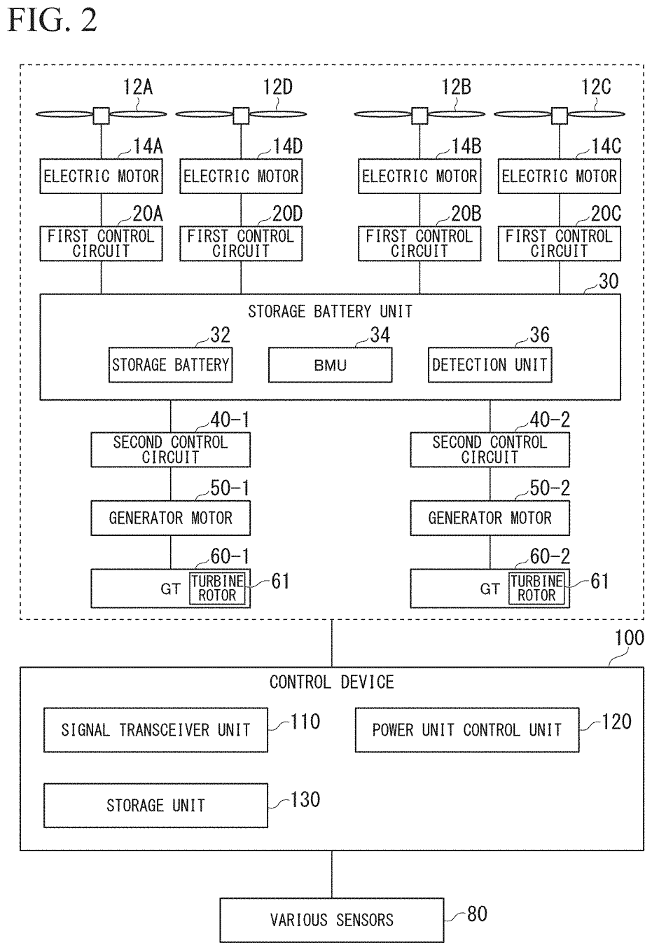

FIG. 2 is a diagram illustrating an example of a functional configuration of the flying object 1. The flying object 1 includes, for example, first control circuits 20A, 20B, 20C, and 20D, a storage battery unit 30, second control circuits 40-1 and 40-2, generator motors 50-1 and 50-2, gas turbine engines (hereinafter referred to as “GTs”) 60-1 and 60-2, various sensors 80, and a control device 100 in addition to the elements illustrated in FIG. 1. Elements with “1” at the end after the reference signs and hyphens are first elements corresponding to the rotor 12A, the rotor 12D, the electric motor 14A, the electric motor 14D, the first control circuit 20A, and the first control circuit 20D, and elements with “2” at the end after the reference signs and hyphens are second elements corresponding to the rotor 12B, the rotor 12C, the electric motor 14B, the electric motor 14C, the first control circuit 20B, and the first control circuit 20C. In the following description, the first elements will be representatively described, and the second elements have the same configurations as the first elements and thus a description thereof will be omitted.

The first control circuit 20A is a power drive unit (PDU) including a drive circuit such as an inverter. The first control circuit 20A supplies electric power obtained by converting electric power supplied from the storage battery unit 30 by switching or the like to the electric motor 14A. The first control circuit 20D is a PDU like the first control circuit 20A and supplies electric power supplied from the storage battery unit 30 to the electric motor 14D. The electric motor 14A drives the rotor 12A, and the electric motor 14D drives the rotor 12D.

The storage battery unit 30 includes, for example, a storage battery 32 (a battery), a battery management unit (BMU) 34, and a detection unit 36. The storage battery 32 is, for example, a battery pack in which a plurality of battery cells are connected in series, in parallel, or in series and parallel. A battery cell of the storage battery 32 is, for example, a secondary battery which can be repeatedly charged and discharged such as a lithium-ion battery (LIB) or a nickel-hydride battery.

The BMU 34 performs cell balancing, detection of an abnormality in the storage battery 32, derivation of a cell temperature in the storage battery 32, derivation of a charging/discharging current in the storage battery 32, estimation of an SOC in the storage battery 32, and the like. The BMU 34 acquires a state of the storage battery 32 on the basis of detection results from the detection unit 36 as described above. The detection unit 36 includes a voltage sensor, a current sensor, and a temperature sensor for measuring the state of charge of the storage battery 32. The detection unit 36 outputs the measurement results such as the measured voltage, current, and temperature to the BMU 34.

The flying object 1 may include a plurality of storage battery units 30. For example, the storage battery units 30 corresponding to the first elements and the second elements may be separately provided. In this embodiment, electric power generated by the generator motors 50 is supplied to the storage battery 32, but may be supplied to the first control circuits 20 and the electric motors 14 without passing through the storage battery 32 (or via the storage battery 32 or selectively).

The second control circuit 40-1 is a power conditioning unit (PCU) including a converter. When the generator motor 50-1 operates as a power generator, the second control circuit 40-1 converts AC electric power generated by the generator motor 50-1 to DC electric power and supplies the DC electric power to the storage battery 32 and/or the first control circuit 20.

When the generator motor 50-1 operates as a motor, the second control circuit 40-1 supplies electric power obtained by converting the electric power supplied from the storage battery unit 30 through switching or the like to the generator motor 50-1.

The generator motor 50-1 (an energy converter) serves as a power generator and a motor.

The generator motor 50-1 is connected to an output shaft of the GT 60-1.

When the generator motor 50-1 operates as a power generator, the generator motor 50-1 is driven with operation of the GT 60-1 and generates AC electric power with the driving. The generator motor 50-1 may be connected to the output shaft of the GT 60-1 via a reduction gear mechanism. When the generator motor 50-1 serves as a motor and supply of fuel to the GT 60-1 is stopped, the generator motor 50-1 causes the GT 60-1 to rotate (idle) and to fall into an operable state. At that time, the second control circuit 40-1 extracts electric power from the storage battery 32 and monitors the generator motor 50-1. Instead of the aforementioned functional configuration, a starter motor may be connected to the output shaft of the GT 60-1, and the starter motor may switch the GT 60-1 to an operable state.

When generator motor 50-1 operates as a motor, the generator motor 50-1 accelerates rotational operation of the GT 60-1 using electric power supplied from the second control circuit 40-1.

The GT 60-1 is, for example, a turbo shaft engine. The GT 60-1 includes, for example, an intake port, a compressor, a combustion chamber, and a turbine which are not illustrated. The compressor compresses intake air suctioned from the intake port. The combustion chamber is disposed downstream from the compressor and combusts a mixture in which the compressed air and fuel are mixed to generate combustion gas. The turbine includes a turbine rotor 61. The turbine is connected to the compressor and rotates integrally with the compressor using a force of the combustion gas. The generator motor 50 connected to an output shaft of the turbine operates by allowing the output shaft of the turbine to rotate with the rotation.

The various sensors 80 include, for example, the rotation speed sensor, a plurality of temperature sensors, a plurality of pressure sensors, a lubricant sensor, an altitude sensor, and a gyro sensor. The rotation speed sensor determines the rotation speed of the turbine. The temperature sensor determines the temperature in the vicinity of the intake port of the GT 60 or the temperature in the vicinity of the downstream side of the combustion chamber. The lubricant sensor determines the temperature of a lubricant supplied to bearings or the like of the GT 60. The pressure sensor determines the pressure in a housing of the GT 60 or the pressure in the vicinity of the intake port of the GT 60. The altitude sensor determines the altitude of the flying object 1. The gyro sensor determines the posture of the airframe 10. The various sensors 80 are provided, for example, in each of the GT 60-1 and the GT 60-2.

The control device 100 includes, for example, a signal transceiver unit 110 (reception portion), a power unit control unit 120 (control portion), and a storage unit 130.

The signal transceiver unit 110 is a communication interface that is communicatively connected to a control device (not illustrated) on the airframe 10 side (hereinafter referred to as an “airframe controller”) and transmits and receives signals thereto and therefrom. The signal transceiver unit 110 may be a functional unit that is implemented by executing a program. The airframe controller (a device controller) is a control device that controls a flight state, an operation state, or the like of the flying object according to detection results from the various sensors, a pilot's operation and steering, an autonomous driving control state, or the like. Examples of the signal mentioned therein include a signal indicating that pre-flight check has been completed (hereinafter referred to as a “pre-flight check completion notification”) which is transmitted from the airframe controller to the power unit control system and a signal indicating that the rotation speed of the gas turbine of the GT 60 has reached a predetermined rotation speed and flight preparation has been completed (hereinafter referred to as a “rotation speed increase completion notification”) which is transmitted from the power unit control system to the airframe controller.

The power unit control unit 120 controls the motors 14, the first control circuits 20, the storage battery unit 30, the second control circuits 40, the generator motor s 50, the GTs 60, and the like on the basis of the operation states thereof, information acquired from the various sensors 80, and signals transmitted from the airframe controller.

Specifically, the power unit control unit 120 controls, for example, the rotation speed of the gas turbine of the GT 60. The power unit control unit 120 controls, for example, the amount of fuel supplied to the GT 60. The power unit control unit 120 performs switching control such that, for example, the generator motor 50 operates as a power generator or a motor. For example, when the generator motor 50 operates as a motor, the power unit control unit 120 controls electric power supplied from the second control circuit 40 to the generator motor 50.

The power unit control unit 120 is implemented, for example, by causing a hardware processor such as a central processing unit (CPU) to execute a program (software). Some or all of such functional units may be implemented by hardware (a circuit unit including circuitry) such as a large-scale integration (LSI) circuit, an application-specific integrated circuit (ASIC), a field-programmable gate array (FPGA), or a graphics processing unit (GPU), or may be cooperatively implemented by software and hardware. The program may be stored in a storage device (a storage device including a non-transitory storage medium) such as a hard disk drive (HDD) or a flash memory of the control device 100 in advance or may be stored in a detachable storage medium (a non-transitory storage medium) such as a DVD or a CD-ROM and may be installed in the HDD or the flash memory of the control device 100 by setting the storage medium to a drive device.

The storage unit 130 stores various types of data and various programs which are used in operation of the power unit control system. The storage unit 130 is implemented, for example, by an HDD, a flash memory, an electrically erasable programmable read-only memory (EEPROM), a read-only memory (ROM), or a random-access memory (RAM).

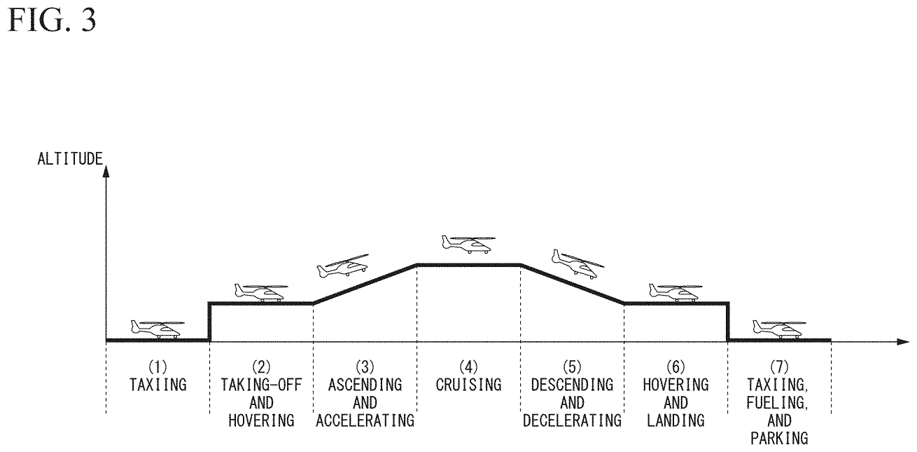

The control device 100 and the airframe controller control the aforementioned functional units such that the flying object 1 takes off or lands or the flying object 1 flies in a predetermined flight state. The control device 100 and the airframe controller control the flying object 1 on the basis of flight information. Flight information is, for example, information acquired from the detection results from the various sensors 80 or the flight state of the flying object 1 in accordance with a control signal. The power unit control unit 120 controls the GTs 60 on the basis of a required output corresponding to the flight state of the flying object 1 and/or a state of charge of the storage battery 32 as illustrated in FIG. 3.

[Description of Flight State]

FIG. 3 is a diagram illustrating the flight state of the flying object 1. As illustrated in FIG. 3, the flying object 1 performs (1) taxiing, performs (2) taking-off and hovering, performs (3) ascending and accelerating, and performs (4) cruising. Then, the flying object 1 performs (5) descending and decelerating, performs (6) hovering and landing, and performs (7) taxiing, fueling, and parking.

For example, the required output in the flight state in which the flying object 1 performs (2) taking-off and hovering or (6) hovering and landing out of the aforementioned flight states is likely to be greater than the required output in the other flight states. The required output in a flight state is electric power (a total of electric power which is needed to be supplied to the motors 14) required for the flying object 1 to transition to a flight state corresponding to a control signal or to maintain the flight state. The control device 100 supplies the required output to the motors 14 and controls the flying object 1 in the flight state corresponding to the control signal by causing the motors 14 to drive the rotors 12 on the basis of the required output.

For example, when predetermined conditions are satisfied, the power unit control unit 120 causes the GT 60-1 and/or the GT 60-2 to operate. The predetermined conditions include, for example, a condition that the flight state is (1), (2), (3), or (6) and a condition that the SOC of the storage battery becomes less than a predetermined value (or the SOC is predicted to become less than the predetermined value within a predetermined time). The predetermined conditions may be arbitrary conditions.

[Flowchart]

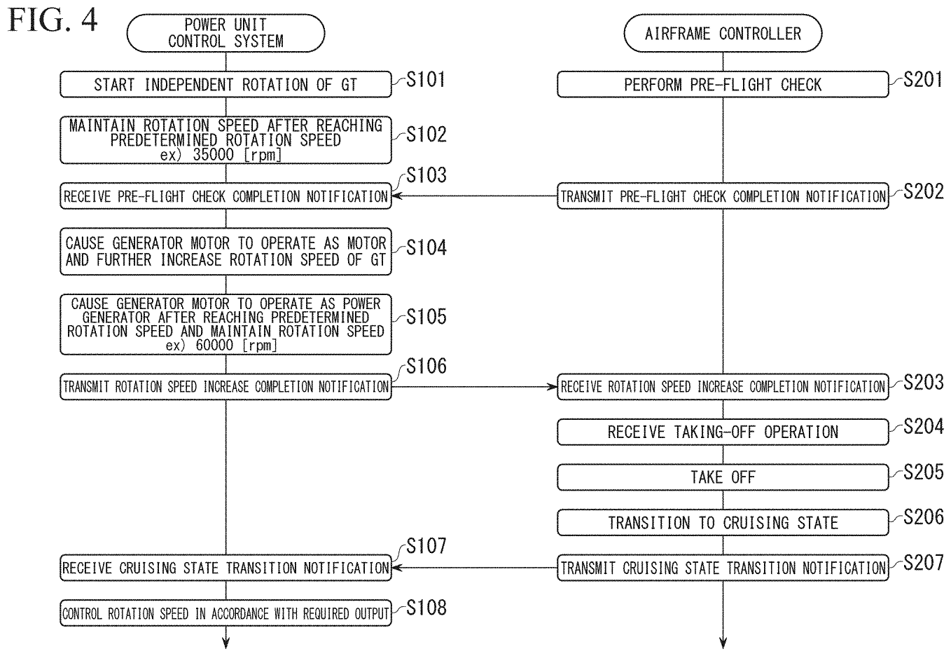

FIG. 4 is a flowchart illustrating a flow of operations performed by the power unit control system according to the embodiment of the present invention. The operations illustrated in this flowchart are an example of operations which are performed by the flying object 1 at the time of taking off. For the purpose of easy understanding, timings of operations of the airframe controller which cooperates with the power unit control system will be described together. The operations of the power unit control system and the airframe controller illustrated in the flowchart correspond to operations in the flight states from (1) taxing to (4) cruising of the flying object 1 in FIG. 3. Some of the operations in the flowchart may be omitted or another operation may be added. The order of operations may be changed.

First, the power unit control unit 120 of the control device 100 in the power unit control system starts independent rotation of the GTs 60 (Step S101) and performs control for increasing the rotation speed until the rotation speed reaches the predetermined rotation speed (rotation speed increase control). When the GTs 60 reach a predetermined rotation speed (for example, 35,000 [rpm]), the power unit control unit 120 stops the increase of the rotation speed and sustains the predetermined rotation speed (Step S102).

On the other hand, the airframe controller receives, for example, a taking-off preparation operation from a pilot or the like and performs pre-flight check of the airframe (Step S201). When pre-flight check is completed, the airframe controller transmits a pre-flight check completion notification (a predetermined first signal) to the power unit control system (Step S202).

The signal transceiver unit 110 of the control device 100 in the power unit control system receives the pre-flight check completion notification transmitted from the airframe controller (Step S103). When the signal transceiver unit 110 receives the pre-flight check completion notification, the power unit control unit 120 performs switching control such that the generator motors 50 operate as a motor. Accordingly, the generator motor 50 operates as a motor and accelerates rotational driving of the GTs 60 using electric power supplied from the second control circuits 40. The power unit control unit 120 increases the rotation speed until the GTs 60 reach a predetermined rotation speed (Step S104).

When the GTs 60 reach the predetermined rotation speed (for example, 60,000 [rpm]), the power unit control unit 120 performs switching control such that the generator motors 50 operate as a power generator. The power unit control unit 120 stops the increase of the rotation speed of the GTs 60 and sustains the predetermined rotation speed (Step S105). When the increase of the rotation speed of the GTs 60 is stopped by the power unit control unit 120, the signal transceiver unit 110 transmits the rotation speed increase completion notification to the airframe controller (Step S106).

The airframe controller receives the rotation speed increase completion notification transmitted from the power unit control system (Step S203). When the rotation speed increase completion notification is received and, for example, a pilot steers the airframe, the airframe controller may display the rotation speed increase completion notification on a display or the like provided in the airframe (for example, a cockpit). After the rotation speed increase completion notification has been received, the airframe controller receives, for example, a pilot's taking-off operation (Step S204). When the taking-off operation is received, the airframe controller controls the airframe 10 to allow the flying object 1 to take off (Step S205).

When the flying object 1 reaches a predetermined altitude, the airframe controller performs switching control such that the flight state of the airframe 10 is switched to a cruising state (Step S206). The switching control to the cruising state mentioned herein is, for example, control such as stop of acceleration of a flight speed and transition from ascending flight to horizontal flight of the flying object 1. When switching control to the cruising state is completed, the airframe controller transmits a cruising state transition notification to the power unit control system (Step S207).

The signal transceiver unit 110 of the control device 100 in the power unit control system receives the cruising state transition notification transmitted from the airframe controller (Step S107). After the cruising state transition notification has been received, the power unit control unit 120 appropriately controls the rotation speed of the GTs 60 according to a required output (Step S108). Through the aforementioned processes, the flow of operations of the power unit control system when the flying object 1 takes off in FIG. 4 ends.

[Control for Preventing Generation of Thermal Stress]

When the GTs 60 start, the temperature of an outer edge part of the turbine rotor 61 provided in the GTs 60 increases rapidly. Accordingly, a difference in temperature occurs between the outer edge part and a central part of the turbine rotor 61. Thereafter, the temperature of the central part of the turbine rotor 61 increase slowly due to thermal conduction from the outer edge part. In the metallic inside of the turbine rotor 61, thermal stress is generated due to a temperature gradient in the meanwhile. This thermal stress causes metal fatigue in the turbine rotor 61 and causes reduction of a lifespan of the GTs 60. Regarding this problem, with the power unit control system according to the embodiment, it is possible to prevent occurrences of metal fatigue in the turbine rotor 61 and to extend the lifespan of the GTs 60 by reducing generation of thermal stress.

Specifically, the power unit control system according to the embodiment reduces generation of thermal stress using a centrifugal force which is generated with rotation of the turbine rotor 61 of the GTs 60. When the rotation of the turbine rotor 61 is accelerated such as at the time of taking off at which the GTs 60 start, compressive stress is generated in the metallic inside of the turbine rotor 61 by heating. The power unit control system according to the embodiment increases the rotation speed of the GTs 60 to a target rotation speed for a shorter time (more rapidly) than in a comparative example when the rotation speed is increased.

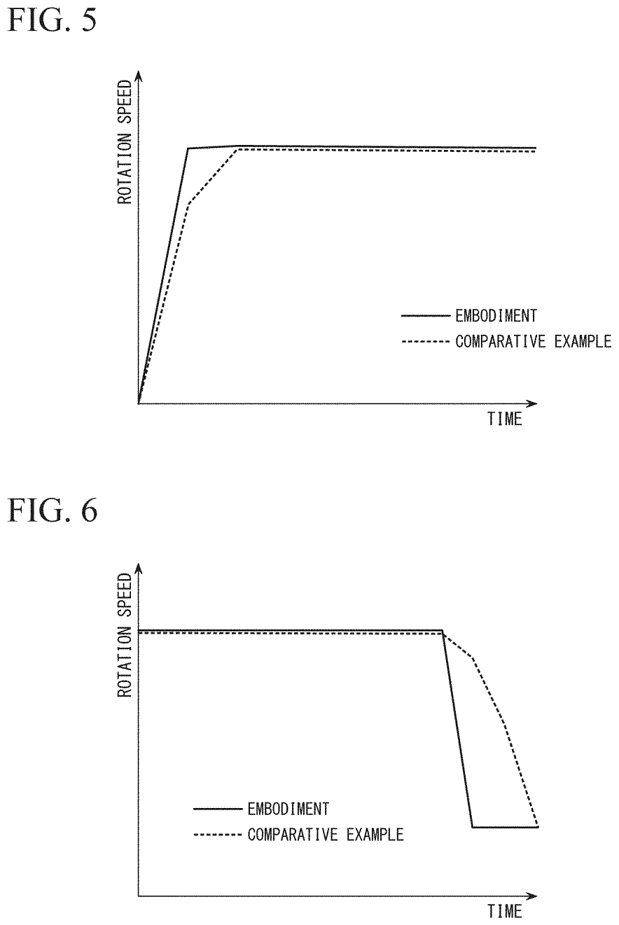

FIG. 5 is a diagram illustrating rotation control of the GTs 60 of the power unit control system according to the embodiment of the present invention at the time of taking off through comparison with a comparative example. In the graph illustrated in FIG. 5, the vertical axis represents the rotation speed of the GTs 60, and the horizontal axis represents the time. The rotation speed in the power unit control system according to the embodiment is indicated by a solid line, and the rotation speed in the comparative example is indicated by a dotted line. As illustrated in FIG. 5, the power unit control system according to the embodiment increases the rotation speed of the GTs 60 to a target rotation speed for a shorter time than in the comparative example, when the pre-flight check completion notification is received.

A centrifugal force generated in the rotating turbine rotor 61 cancels out a part of compressive stress generated in the metallic inside of the turbine rotor 61 by heating. As the rotation speed of the GTs 60 is increased for a shorter time, the centrifugal force generated in the rotating turbine rotor 61 increases more rapidly and thus the effect of cancelling out the compressive stress is further enhanced. In this way, with the power unit control system according to the embodiment, it is possible to prevent occurrences of metal fatigue of the turbine rotor 61 and to extend the lifespan of the GTs 60 by increasing the rotation speed of the GTs 60 for a shorter time.

On the other hand, when the rotation of the turbine rotor 61 of the GTs 60 decelerates, tensile stress is generated in the metallic inside of the turbine rotor 61 by cooling. The power unit control system according to the embodiment decreases the rotation speed of the GTs 60 to a target rotation speed for a shorter time than in the comparative example when the rotation speed is decreased.

FIG. 6 is a diagram illustrating rotation control of the GTs 60 of the power unit control system according to the embodiment of the present invention through comparison with a comparative example. In the graph illustrated in FIG. 6, the vertical axis represents the rotation speed of the GTs 60, and the horizontal axis represents the time. The rotation speed in the power unit control system according to the embodiment is indicated by a solid line, and the rotation speed in the comparative example is indicated by a dotted line. As illustrated in FIG. 6, the power unit control system according to the embodiment decreases the rotation speed of the GTs 60 to a target rotation speed for a shorter time than in the comparative example when the reception portion receives a decrease signal (a predetermined second signal). The decrease signal is, for example, a signal indicating that the rotation speed of the GTs 60 is decreased. The decrease signal is, for example, a signal which is output when a required output is equal to or less than a predetermined value or a signal indicating that rotation speed decrease control for decreasing the rotation speed of the GTs 60 to a predetermined rotation speed is performed.

As the rotation speed of the GTs 60 is decreased for a shorter time, the centrifugal force generated in the rotating turbine rotor 61 is decreased more rapidly and thus the tensile stress in the metallic inside of the turbine rotor 61 generated due to the centrifugal force is decreased. Accordingly, with the power unit control system according to the embodiment, it is possible to reduce occurrences of metal fatigue of the turbine rotor 61 and to extend the lifespan of the GTs 60. In the aforementioned flow of processes, the power unit control system may control a mechanism for adjusting a current, a load, or the like applied to the power generator and increase the load of the power generator such that the rotation speed is further decreased.

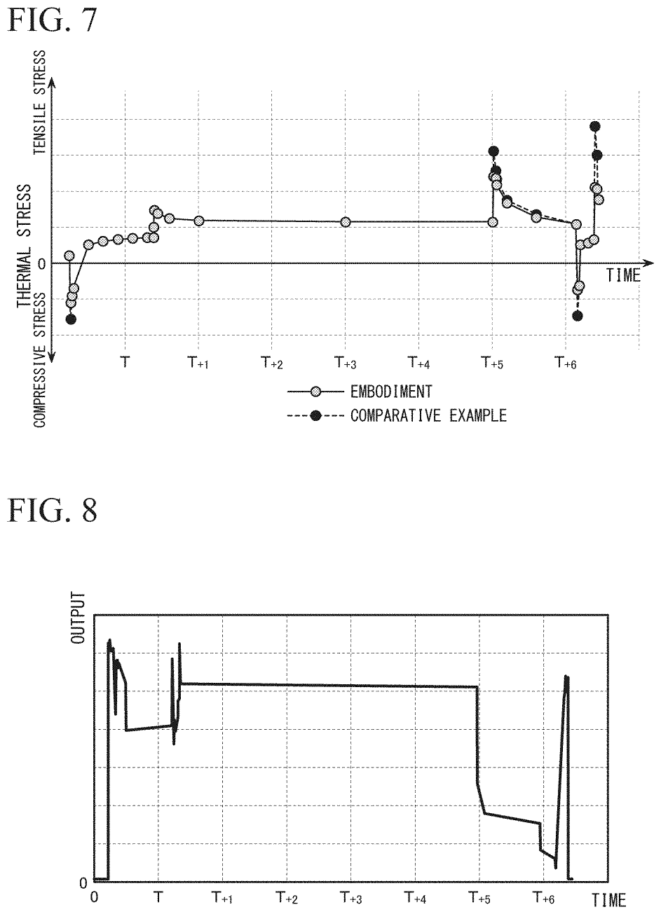

FIGS. 7 and 8 are diagrams illustrating an example of a simulation result of reducing thermal stress in the power unit control system according to the embodiment of the present invention. In the graph illustrated in FIG. 7, the vertical axis represents thermal stress generated in the metallic inside of the turbine rotor 61 of the GTs 60, in which the tensile stress becomes greater toward the top of the graph and the compressive stress becomes greater toward the bottom of the graph. In the graph illustrated in FIG. 7, the horizontal axis represents the time. The thermal stress in the power unit control system according to the embodiment is indicated by a solid line, and the thermal stress in the comparative example is indicated by a dotted line. The vertical axis of the graph illustrated in FIG. 8 represents the output of the GTs 60, and the horizontal axis of the graph illustrated in FIG. 8 represents the time corresponding to FIG. 7.

As illustrated in FIG. 7, compressive stress is generated in the metallic inside of the turbine rotor 61 at the time of taking off (the left part of the graph). However, with the power unit control system according to the embodiment, it can be seen that the generated compressive stress is decreased at a position at which the output changes greatly in comparison with the comparative example. As illustrated in FIG. 7, tensile stress (and compressive stress at some timings) is generated in the metallic inside of the turbine rotor 61 in the right part of the graph.

However, with the power unit control system according to the embodiment, it can be seen that the generated tensile stress (and the compressive stress at some timings) is decreased at a position at which the output changes greatly in comparison with the comparative example.

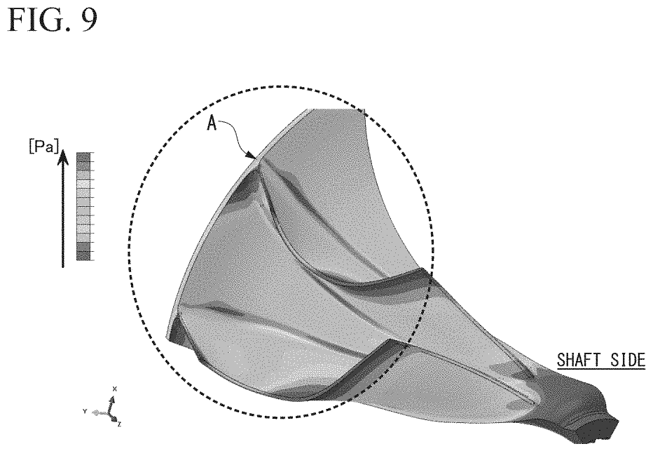

FIG. 9 is a diagram illustrating an example of a stress distribution in the turbine rotor according to the comparative example. FIG. 9 illustrates a stress distribution when the GTs 60 rotate at a predetermined rotation speed (for example, 6000 rpm).

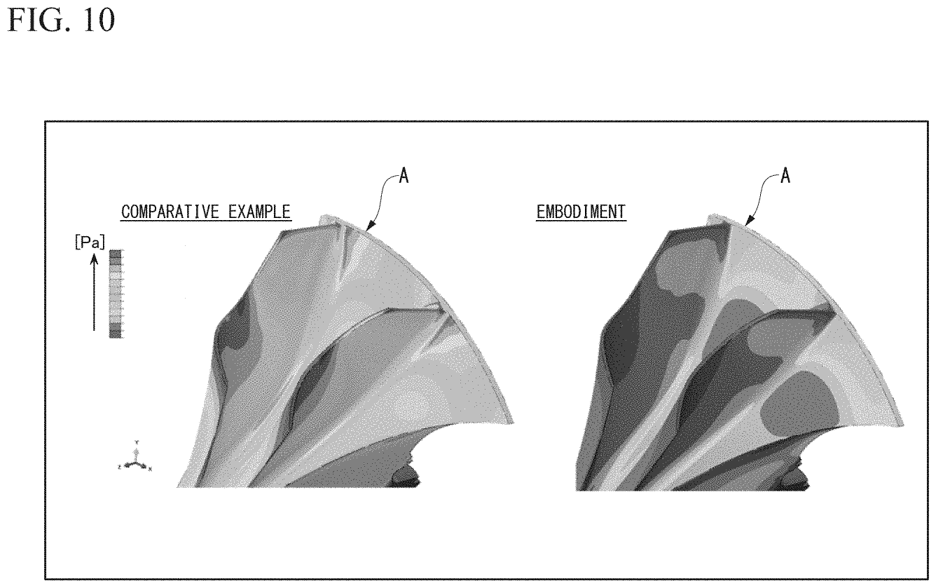

As illustrated in FIG. 9, the stress distribution in the vicinity of an area A increases. FIG. 10 is an enlarged view of a part of the turbine rotor in FIG. 9 (a dotted circle in FIG. 9). As illustrated in FIG. 10, stress on the turbine rotor is reduced by performing the control according to this embodiment. Particularly, stress in the area A is reduced. In this way, it is possible to prevent occurrences of metal fatigue.

[Control for Preventing Input of Heat to GT]

When the rotation speed of the GTs 60 is increased for a shorter time at the time of taking off as in the power unit control system according to the embodiment, it is thought that more heat is input by the turbine rotor 61 and larger thermal stress is generated when the rotation speed is increased with only independent rotation of the GTs 60. Accordingly, the power unit control system according to the embodiment accelerates the increase of the rotation speed of the GTs 60 by causing the generator motor 50 to operate as a motor as in the operation of Step S104 in FIG. 4.

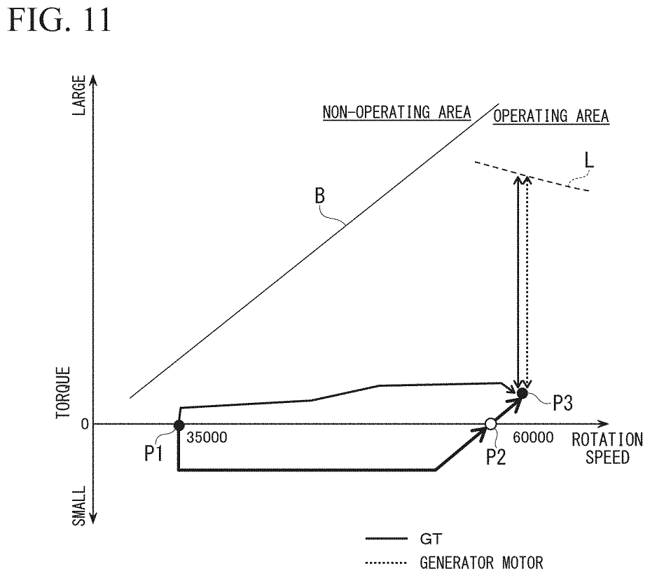

FIG. 11 is a diagram illustrating torque control when the rotation speed of the GTs 60 is increased by the power unit control system according to the embodiment of the present invention. The vertical axis of the graph illustrated in FIG. 11 represents a magnitude of a torque of the GTs 60, and the horizontal axis represents the rotation speed of the GTs 60. In the graph illustrated in FIG. 11, control of the torque and the rotation speed of the GTs 60 is indicated by a solid line, and control of the torque and the rotation speed of the generator motors 50 is indicated by a dotted line. When the torque of the generator motors 50 is minus, it means a state in which the rotation of the GTs 60 is accelerated. When the torque of the generator motors 50 is plus, it means a state in which electric power is generated. An upper-right dotted line in the graph indicates an operating line L representing a combination of torque and rotation speed in which fuel efficiency is optimal. The GTs 60 can operate in the right range of a boundary B, and misfire in a state in which fuel is rich in the left range thereof.

Operating points P1 to P3 are illustrated in FIG. 11. The operating point P1 corresponds to the operation state of Step S102 in the flowchart illustrated in FIG. 4. That is, the operating point P1 corresponds to a state in which the GTs 60 reach a predetermined rotation speed (for example, 35,000 [rpm]) with independent rotation of the GTs 60 and sustain the predetermined rotation speed. A section between the operating point P1 and the operating point P2 corresponds to the operation state of Step S104 in the flowchart illustrated in FIG. 4. That is, the section between the operating point P1 and the operating point P2 corresponds to a state in which the GTs 60 increases the rotation speed from the predetermined rotation speed (for example, 35,000 [rpm]) to the vicinity of a predetermined rotation speed (for example, 60,000 [rpm]) with independent rotation of the GTs 60 and acceleration of the generator motors 50. At the operating point P2, acceleration by the generator motors 50 is stopped. The operating point P3 corresponds to the operation state of Step S105 in the flowchart illustrated in FIG. 4. That is, the operating point P3 corresponds to a state in which the GTs 60 sustain the predetermined rotation speed (for example, 60,000 [rpm]) with independent rotation of the GTs 60.

When the rotation speed of the GTs 60 is increased (for example, from 35,000 [rpm] to 60,000 [rpm]), the power unit control unit 120 may reduce supply of fuel to the GTs 60 in order to prevent an input of heat to the turbine rotor 61. For example, the power unit control unit 120 may perform control such that the amount of fuel supplied to the GTs 60 is not greater than the amount of fuel supplied to the GTs 60 at a time point before the generator motor 50 operates as a motor. For example, the power unit control unit 120 may perform control such that a smallest amount of supplied fuel in a range in which the GTs 60 do not misfire is achieved. The reason the power unit control unit 120 does not fully stop supply of fuel to the GTs 60 is that deterioration in members of a fuel ignition system due to reignition is not caused.

As illustrated in FIG. 11, since supply of fuel to the GTs 60 is reduced when the rotation speed of the GTs 60 is increased from 35,000 [rpm] to 60,000 [rpm], the torque based on the independent rotation of the GTs 60 is decreased. In the meantime, instead, an increase of the rotation speed of the GTs 60 is achieved with acceleration by the generator motors 50.

When the rotation speed of the GTs 60 reaches the vicinity of the predetermined rotation speed (for example, 60,000 [rpm]), the power unit control unit 120 performs switching such that the generator motors 50 operate as a power generator again, stops acceleration by the generator motors 50, and perform control such that the predetermined rotation speed is sustained with the independent rotation of the GTs 60. At this time, as illustrated in FIG. 11, the power unit control unit 120 performs control such that the torque from the GTs 60 has a value on an operating line L indicating a combination of the torque and the rotation speed at which fuel efficiency is optimal.

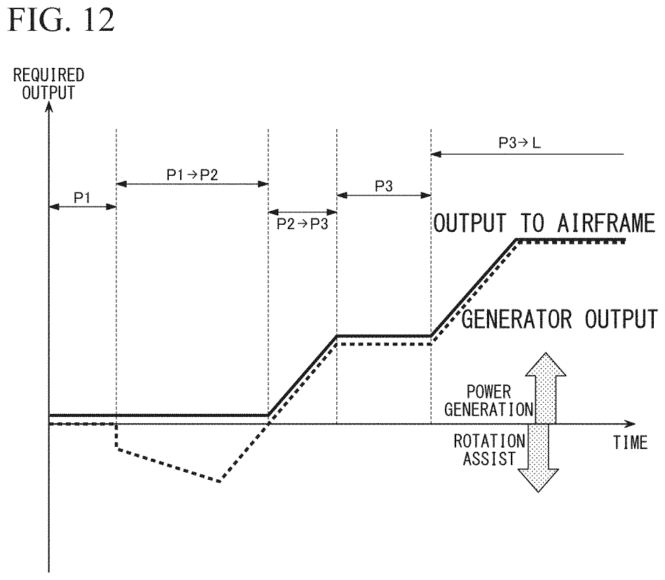

FIG. 12 is a diagram illustrating an example of a required output corresponding to FIG. 11 (a required output for the motor 14). The vertical axis in FIG. 12 represents the required output, and the horizontal axis in FIG. 12 represents the time. In FIG. 12, change of the required output by time zones and correspondence between the time zones and the operating points P1 to P3 in FIG. 11 are illustrated. In FIG. 12, the required output of the time zone in the section indicated by P3 is a required output with which the flying object 1 does not rise up regardless of environmental conditions of the flying object 1. For example, it is a required output with which an additional load (a load such as luggage) is not applied to the flying object 1 and the flying object 1 does not rise up even in a state in which windy conditions are bad. In FIG. 12, the required output after it has increased to a constant value in the time zone of the section indicated by P3→L (that is, the required output at the rightmost time point in the graph) is a required output which corresponds to L in FIG. 11 and in which the flying object 1 can take off satisfactorily regardless of the environmental conditions. For example, it is a required output with which the flying object 1 can take off satisfactorily even when windy conditions are not good and there is an additional load (a load such as luggage). As described above, with the power unit control system, it is possible to control the GTs 60 and the generator motors 50 such that the required output is satisfied and to reduce thermal stress.

As described above, with the power unit control system according to the embodiment, it is possible to more rapidly change the centrifugal force acting on the turbine rotor 61 of the GTs 60 by changing (increasing or decreasing) the rotation speed of the GTs 60 for a shorter time and to reduce thermal stress generated in the metallic inside of the turbine rotor 61. Accordingly, it is possible to prevent occurrences of metal fatigue. According to this embodiment, since a new device such as a magnetic field generating mechanism does not need to be installed in the power unit control system, it is possible to prevent an increase in size, weight, and cost of the device.

As described above, with the power unit control system according to the embodiment, it is possible to more rapidly increase the rotation speed of the GTs 60 and to compensate for a responsiveness delay of the GTs 60 by causing the generator motors 50 to operate as a motor for accelerating the rotation of the GTs 60 when the rotation speed of the GTs 60 is increased for a shorter time.

As described above, with the power unit control system according to the embodiment, since an input of heat to the turbine rotor 61 can be prevented by increasing the rotation speed of the GTs 60 without increasing the amount of fuel supplied to the GTs 60, it is possible to reduce generation of thermal stress. Accordingly, it is possible to prevent occurrences of metal fatigue.

While a mode for carrying out the present invention has been described above with reference to an embodiment, the present invention is not limited to the embodiment, and various modifications and substitutions can be performed thereon without departing from the gist of the present invention.

What is claimed is:

1. A power unit control system comprising:
a gas turbine including a turbine rotor;
an energy converter being able to operate as a power generator that generates electric power with rotation of the gas turbine;
a battery that stores electric power generated by the energy converter;
a reception portion that receives a signal which is transmitted from a device controller that controls a device operating using the electric power stored in the battery or electric power generated by the energy converter; and
a control portion that performs rotation speed increase control which increases a rotation speed of the gas turbine to a predetermined rotation speed when a predetermined first signal is received by the reception portion.

2. The power unit control system according to claim 1,
wherein the energy converter operates as an electric motor that accelerates rotation of the gas turbine using electric power stored in the battery when the control portion performs the rotation speed increase control.

3. The power unit control system according to claim 2,
wherein the control portion reduces an amount of fuel which is supplied to the gas turbine when the control portion performs the rotation speed increase control.

4. The power unit control system according to claim 1,
wherein the control portion performs rotation speed decrease control that decreases a rotation speed of the gas turbine to a predetermined rotation speed when a predetermined second signal is received by the reception portion, and
wherein the control portion increases a load of the power generator such that the rotation speed decreases in the rotation speed decrease control.

5. The power unit control system according to claim 1,
wherein the device is a flying object, and
wherein the predetermined first signal is a check completion signal indicating that the flying object is prepared for start of flight before the flying object flies by autonomous driving or a pilot's steering of the flying object.

6. The power unit control system according to claim 4,
wherein the device is a flying object, and
wherein the predetermined second signal is a signal which is output when a required output by autonomous driving or a pilot's steering of the flying object is equal to or less than a predetermined value.

7. A power unit control method comprising:
a reception step of receiving a signal which is transmitted from a device controller that controls a device including a gas turbine including a turbine rotor, an energy converter being able to operate as a power generator that generates electric power with rotation of the gas turbine, and a battery that stores electric power generated by the energy converter, the device operating using the electric power stored in the battery or electric power generated by the energy converter; and
a control step of performing rotation speed increase control that increases a rotation speed of the gas turbine to a predetermined rotation speed when a predetermined signal is received in the reception step.

8. A non-transitory computer-readable recording medium that includes a power unit control program, the power unit control program causing a computer to perform:
a reception step of receiving a signal which is transmitted from a device controller that controls a device including a gas turbine including a turbine rotor, an energy converter being able to operate as a power generator that generates electric power with rotation of the gas turbine, and a battery that stores electric power generated by the energy converter, the device operating using the electric power stored in the battery or electric power generated by the energy converter; and
a control step of performing rotation speed increase control that increases a rotation speed of the gas turbine to a predetermined rotation speed when a predetermined signal is received in the reception step.
